(19) United States
(12) Patent Application Publication
(10) Pub. No.: US 2004/0189327 A1
(43) Pub. Date: Sep. 30, 2004

(54) CAPACITIVE SENSOR

(75) Inventor: Steven Basil Al-Rawi, Irvine, CA (US)

Correspondence Address: STEVEN AL-RAWI, 26 AMORET DRIVE, IRVINE, CA, 92602, US

(73) Assignee: Mr. Steven Al-Rawi, Irvine (US)

(21) Appl. No.: 10/249,316

(22) Filed: Mar. 31, 2003

(51) Int. Cl. G01R 27/26

(52) U.S. Cl. 324/658

(57) ABSTRACT

A method of manufacturing a low cost, high resolution, contactless, absolute rotational position sensor is disclosed. A coupling disc and a transceiver disc are the only required elements. The coupling disc can be manufactured as a simple two sided printed circuit board. A common 4 layer printed circuit board can act as the transceiver element and the circuit board for implementing the signal processing and output driver. The coupling disc capacitively couples drive signals originating on the transceiver disc to receiving tracks on the transceiver disc. Full 360 degree position decoding can be achieved. Potentials measured on the receiver nodes are processed to obtain an absolute position and a syndrome. The syndrome is a numerical result that can be used to predict the integrity of the position data. The maximum resolution of the sensor is 4N*(A/D resolution), where N is the larger of M and N above. Normally, resolution is limited to 2N*(A/D resolution) to allow for a halving of the coupling disc gap without accuracy degradation. A sensor conforming to the invention can tolerate several mils of axial movement or runout in the coupling disc with minimal effect on sensor accuracy.

### SUMMARY OF INVENTION

The invention is a configuration of a contactless absolute position sensor that has several advantages compared with other sensors of similar function. It can be fabricated at low cost from commercially available FR4 printed circuit boards assembled to tolerances typical of potentiometer manufacture. Potentiometers, a common example of a low cost absolute position sensor, wear relatively quickly due to the dragging of the contact along the resistive element. Furthermore, position information is often corrupted by contaminants which may be deposited on the sensing element or contact surface. Airborne particles, wear debris generated by the sliding contact, friction generated polymer, and atmospheric condensates are some of the many sources of contamination. Contactless absolute position sensors which offer high positional resolution, adequate environmental durability and high reliability, are usually costly. Expensive materials, low allowable assembly tolerances or component tolerances, expensive processes and a large number of manufacturing operations are some of the cost adders which plague these sensors.

The invention, is comprised of a transceiver element and a coupling element. With the transceiver element and coupling element situated as specified, excitations applied to the transceiver element completely determines the rotational position of the coupling element within the specified range and resolution. The specified range can be up to 360 degrees. Excitation, Processing and Output drive circuitry can be included on the circuit board which is used as the transceiver disc.

The invention comprises: A specific patterns of conductive areas on adjacent opposing surfaces of the coupling and transceiver element; A specification of how these conductive patterns are attached to form circuit nodes; A specification for applying potentials to two nodes of the transceiver element; An algorithm for generating an angular position value and reliability value from differential potentials measured between receiver nodes on the transceiver element. The sensor so comprised exhibits decreased sensitivity to: externally generated varying potentials; variations in the spatial separation of the two elements; variations from ideal form of element surfaces; offset and gain errors in the potential measuring device.

The manner in which the invention achieves the benefits stated will be easily discernable from the detailed description.

### BRIEF DESCRIPTION OF DRAWINGS

FIG. 1 is a side sectional view of a rotary position sensor containing the invention features;

FIG. 2 is a top view of the coupling disc of the sensor shown in FIG. 1;

FIG. 3 is a bottom view of the transceiver disc of the sensor shown in FIG. 1;

FIG. 4 is a simplified schematic diagram of the sensor shown in FIG. 1;

FIG. 5 is a graph of selected transceiver node potentials versus time for an operating sensor;

FIG. 6 is a graph of normalized differential transceiver node potentials versus position;

FIG. 7 is a graph of normalized differential transceiver node potentials versus position;

FIG. 8 defines an abbreviated notation for differences of transceiver node potentials at time 81;

FIG. 9 defines an abbreviated notation for differences of transceiver node potentials at time 84;

FIG. 10 is an equation defining the term A in the position equation;

FIG. 11 is an equation defining the term B in the position equation;

FIG. 12 is an equation defining the term C in the position equation;

FIG. 13 is an equation defining the term D in the position equation;

FIG. 14 is an equation defining the normalized A;

FIG. 15 is an equation defining the normalized B;

FIG. 16 is an equation defining the normalized C;

FIG. 17 is an equation defining the normalized D;

FIG. 18 is the definition of the interval position function f( );

FIG. 19 is the definition of 0 degrees position;

FIG. 20 is the definition of the rotational angle φ;

FIG. 21 is the definition of fractional position P;

FIG. 22 is the definition of numerical operator INT( );

FIG. 23 is the definition of numerical operator FRACT( );

FIG. 24 is the equation used to calculate fractional position P;

FIG. 25 is an equation used to estimate the fractional position P;

FIG. 26 is an equation which implicitly defines the error term Syndrome;

FIG. 27 is a relation defining the allowable limits of the error term;

FIG. 28 is an expression for evaluating the term Q in FIG. 24;

FIG. 29 is the definition of the function H( ) occurring in FIG. 28;

### DETAILED DESCRIPTION

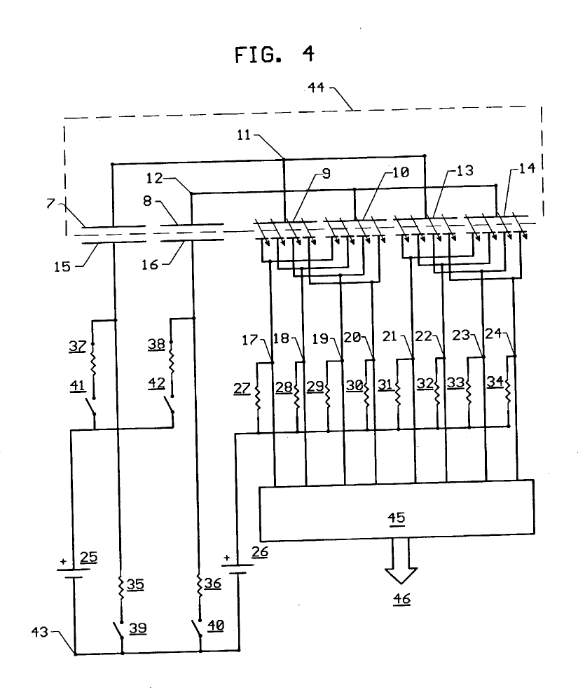

The Rotary capacitive sensor shown in FIG. 1 is a particular embodiment of a sensor which includes the invention. It includes a coupling disc 1, which is bonded to a rotor hub 2. Also comprising the sensor is a transceiver disc 4 which is bonded to the sensor housing 5. The embodiment shown is intended to be attached to a rotating shaft which extends orthogonally from a flat surface. Details of the device to which the sensor is attached are irrelevant except to note that when so attached, the coupling disc may rotate about an axis centered in bore 3 and orthogonal to surface 6. The housing 5 and rotor hub 2 are an example of a physical mechanism used to prevent any motion, other than rotation about the shaft axis, of the coupling disc 1 relative to the transceiver disc 4. In the particular embodiment, the rotor hub 2 and the housing 5 are aluminum. When these two parts consist of materials with high electrical conductivity, they decrease the sensitivity of sensor output to external varying potentials. The housing may be connected electrically to circuit node 43, shown in FIG. 4 to minimize external potentials relative to this node.

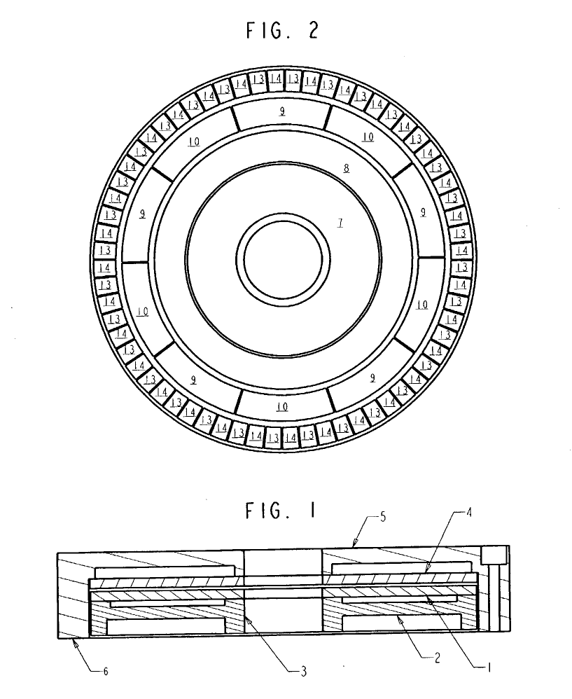

FIG. 2 shows the surface of the coupling disc adjacent to the transceiver disc. FIG. 4 is a schematic representation of the sensor. Elements within the dashed rectangle 44 in FIG. 4 are physically realized on the coupling disc.

The coupling disc contains four annular tracks. Inner tracks copper annulus 7 and copper annulus 8 function as the capacitor plates 7 and 8 shown in FIG. 4. The area of plates 7 and 8 are approximately equal. The next annular track consists of 10 identical annular copper segments spaced by 36 degrees. Every other segment comprises capacitor plate 9 and is electrically connected to node 11 as shown in FIG. 4. The remaining 5 annular copper segments 10 function as capacitor plate 10 and are electrically connected to node 12. The outer most track of the coupling disc consists of 64 equally spaced identical annular copper segments. Every other segment functions as capacitor plate 13 and is a part of electrical node 11. The remaining 32 copper segments function as capacitor plate 14 and are connected to electrical node 12. The top surface of the coupling disc is a contiguous sheet of copper except where etched away to provide isolation from connecting traces. This copper sheet decreases output sensitivity to stray fields. In the particular embodiment, the coupling disc is fabricated from 0.063 inch thick FR4 epoxy glass. In general, the top copper sheet must not result in excessive cross coupling of node 11 to node 12.

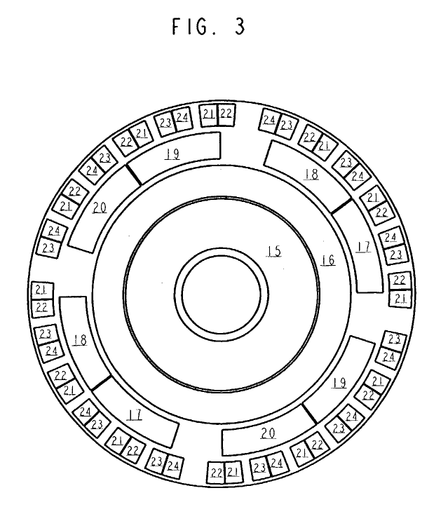

Connection of the segments are made with 0.007 inch wide traces. In general, the area of the connecting traces is kept to a minimum. Ideally, the capacitive coupling between node 11 and each of transceiver nodes 17, 18, 19 and 20 shown in FIG. 3 is identical to the capacitive coupling between node 12 and each of the nodes 17, 18, 19 and 20 when the coupling disc has been rotated 36 degrees. Ideally the capacitive coupling of node 11 with each of transceiver nodes 21, 22, 23 and 24 shown in FIG. 3 is identical to the capacitive coupling of node 12 with each of the transceiver nodes 27, 22, 23 and 24 when the coupling disc is rotated 5.625 degrees. Non-ideal features in this regard are made as small as practical.

FIG. 3 shows the metalization pattern of the transceiver disc. The metalization consists of annular areas 15 and 16 which oppose areas 7 and 8, respectively, on the coupling disc. These metalized areas function as the capacitor plates 15 and 16 shown in FIG. 4.

In the third annular track from the center is 8 annular segments 17, 18, 19 and 20 that match annular segments 9 and 10 of the coupling disc in size and radial position. They function as the capacitor plates attached to nodes 17, 18, 19 and 20 as shown in FIG. 4. The 8 annular segments are composed of 4 segment pairs, with the spacing between segments of a pair being 36 degrees. Adjacent pairs are spaced 90 degrees apart.

The fourth annular track from the center contains 48 annular segments 21, 22, 23 and 24. Each segment matches segments 13 and 14 of the coupling disc in size and radial position. These metalized areas function as the capacitor plates attached to nodes 21, 22, 23 and 24 as shown in FIG. 4. The 48 annular segments are composed of 24 segment pairs, with the spacing between segments of a pair being 5.625 degrees. Adjacent pairs are spaced by 14.0825 degrees or 19.6875 degrees. The 19.6875 degree spacing occurs 4 times at 90 degrees apart.

To operate the sensor a voltage potential 25 must be applied as shown in FIG. 4. Also, a potential 26 must be applied to the receiving plates 17, 18, 19, 20, 27, 22, 23 and 24 thru resistors 27, 28, 29, 30, 31, 32, 33 and 34. The value of potential 26 is one half the potential 25. In the specific device described resistors 27 through 34 have a value of 4.99K ohms. The resistor values should be equal within practical limitations. The value of potential 25 in the specific device described is 5 volts. As shown in FIG. 4, the potential 25 is connected to drive plate 15 thru resistor 37 in series with switch 41 and to drive plate 16 through resistor 38 in series with switch 42. Drive plates 15 and 16 are also connected to the zero potential node 43 by resistor 35 in series with switch 39 and resistor 36 in series with switch 40, respectively. For the specific device, resistors 35, 36, 37 and 38 have a value of 899 ohms. Switches 39, 40, 41 and 42 are implemented using an integrated circuit of type 74HC4066.

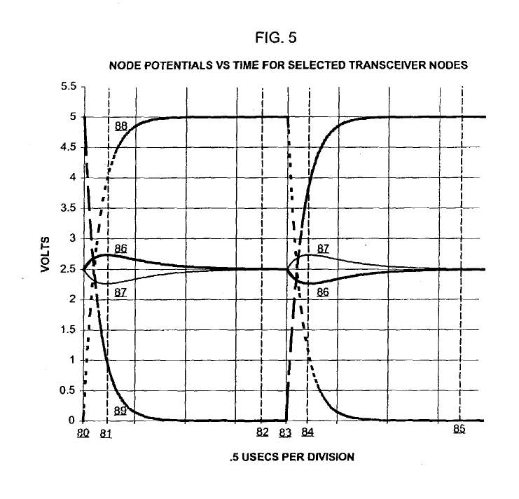

The potential on drive plates 15 and 16 is varied by opening and closing switches 39, 40, 41, and 42 at specified times. Initially all switches are open. At time 80 indicated in FIG. 5 switches 41 and 40 are closed. At time 82, switches 41 and 40 are opened. At time 83 switches 39 and 42 are closed. At time 85 switches 39 and 42 are opened. The switching sequence is repeated for as long as sensor output is required. For the specific sensor described, the switching sequence is repeated every 4 usecs. The potential waveforms shown as 88 and 89 in FIG. 5 are expected on plates 15 and 16 respectively while the specified switching sequence is performed.

The information required to compute the receiver disc position is obtained by measuring potential differences at the times 81 and 84 as shown in FIG. 5. The specific differences measured are: potential at node 17 minus potential at node 18; potential at node 19 minus potential at node 20; potential at node 21 minus potential at node 22; potential at node 23 minus potential at node 24. Waveforms 86 and 87 are the expected potentials vs. time for nodes 22 and 21 respectively with the sensor at 0 degrees. The sensor is at zero degrees in FIG. 1, FIG. 2 and FIG. 3.

The circuit board for the specific device includes ground plates to stabilize the capacitance of transceiver plates 15, 16 and 17 through 24 with respect to ground. The ground plates also reduce unintended cross coupling. The ground plates are electrically connected to node 43. In the particular device, a ground plate of annular shape is separated from plates 15 and 16 by 0.2 mm. The resulting capacitance in conjunction with resistors 35, 36, 37 and 38 largely determine the charge and discharge rate of plates 15 and 16. It is important to stabilize the charge rate of plates 15 and 16 so that the time when the receiver nodes attain their maximums can be accurately predicted. The ground plates above receiver plates 17 through 24 are separated by about 1.2 mm. The choice of separation will depend on available layer positions in the circuit board, measuring device sensitivity, nominal coupling capacitance and measuring device input impedance. The discharge resistors 27 through 34 are also factors in predicting the time maximum receiver node amplitudes occur. 45 is intended to represent circuitry which processes the receiver node potentials into the desired form of output 46. This circuitry may be included as part of the transceiver disc.

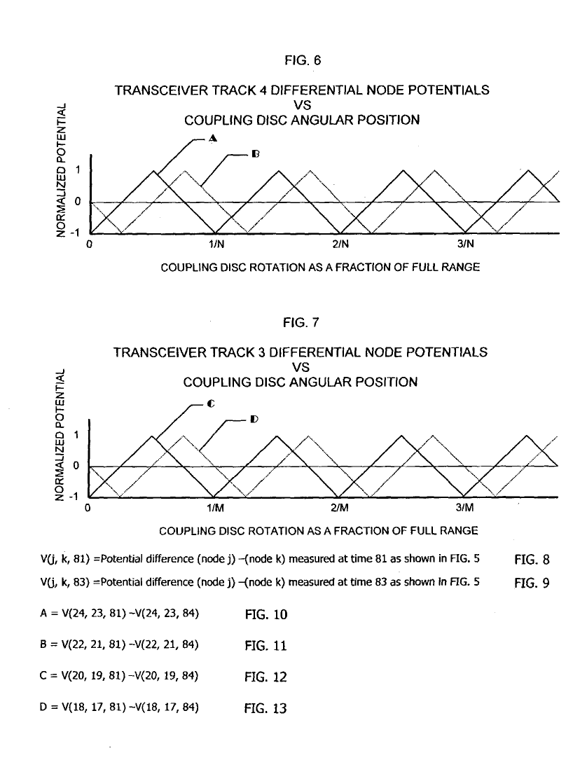

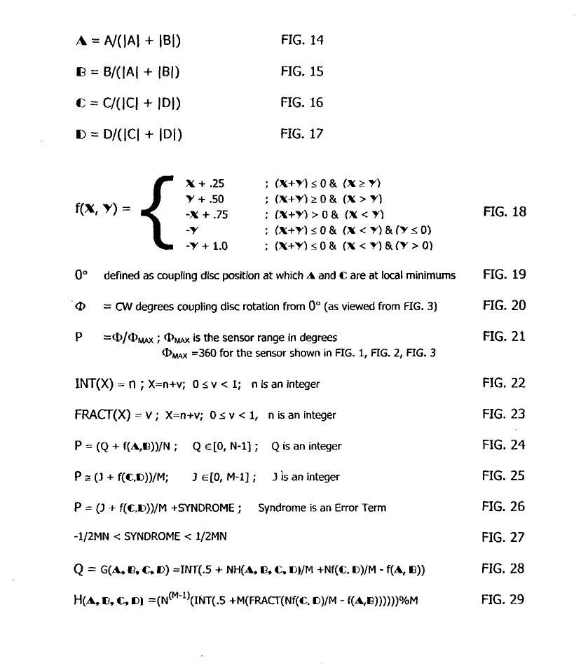

The four potential differences are converted to an angular position by the equation of FIG. 24. The units, direction and origin of the position so calculated are defined by FIG. 21, FIG. 20 and FIG. 19 respectively. The relative angular location of potential difference minimums generated from the third and fourth tracks are determined by the relative positioning of their respective plates when the discs are manufactured. The alignment of minimums for differences A and C as shown in FIG. 6 and FIG. 7 is for computational convenience only. The solution is a continuous function of the differential node potentials provided the error term is limited as shown in the equation of FIG. 27. The error term, referred to as Syndrome, is implicitly defined by the equation in FIG. 26. Small syndrome amplitude is an indication of reliable sensor data. The Syndrome is seen to be the difference in the position calculated using the equation in FIG. 25 from the position calculated using the equation of FIG. 24.

FIG. 28 is a solution for the term Q appearing in the equation of FIG. 24. In FIG. 29, a function of the incremental position terms appearing in the equation of FIG. 28 is defined. FIG. 22 and FIG. 23 define numerical operators appearing in the equations of FIG. 28 and FIG. 29. The evaluation of the incremental position terms is given by the function of FIG. 18. The incremental position terms are a function of the normalized potential difference terms as defined by FIG. 14, FIG. 15, FIG. 16 and FIG. 17. The difference terms prior to normalization are defined in FIG. 10, FIG. 11, FIG. 12, and FIG. 13. The abbreviated notation used in FIG. 10 through FIG. 13 is defined in FIG. 8 and FIG. 9.

Many of the stated benefits can be verified by examining the position calculation. From the equations in FIG. 10 through FIG. 13, it follows that potential variations that are applied equally to both nodes of a node pair will not alter the output. This remains true as long as the measurement is a linear function of the applied potentials. Static offsets in the measuring device are also canceled since the potential difference at time 84 is subtracted from the potential difference at time 81.

From the equations in FIG. 14 through FIG. 17 it follows that signal attenuations which affect both pair sets in a track equally do not affect position. For example, if plates attached to nodes 23 and 24 are attenuated by the same factor K as plates attached to nodes 21 and 22, then the left-hand side of equations of FIG. 10 and FIG. 11 will be attenuated by factor K. It follows that the left-hand side of equations given in FIG. 14 and FIG. 15 remain unchanged.

Coupling of receiver nodes equally disposed between plates 7 and 8 is not required to be equal for accurate sensor operation. An increased coupling to either of plate 7 or 8 will exist on both nodes of the node pair and therefore cancel. This is an important feature since it is difficult to guarantee equal coupling to plates 7 and 8.

It is important to understand the theory of sensor operation so that optimal choices can be made when fabricating sensors of various sizes, resolutions, materials and circuitry. The principal assumption on which the position calculations are based is: The capacitive coupling of a receiver node to the opposed coupling disc node varies linearly with the overlapping area.

In particular, the coupling of node 21 to node 7 is maximal when segments of node 21 are directly opposed to segments of node 13. The coupling of node 21 to node 7 is minimal when the segments of node 21 are directly opposed to segments 14. The coupling of node 21 to node 7 is half way between minimal and maximal when the segments of node 21 are equally disposed between segments 13 and 14. When the principal assumption holds, FIG. 6 is a graph of the potential differences A, B versus position, as defined in equations of FIG. 10 and FIG. 11. FIG. 7 is a graph of the potential differences C, D as defined in equations FIG. 12 and FIG. 13. The peak values have been normalized to one. The graphs show that the absolute value of A summed to the absolute value of B is constant for all positions. This is the basis for the normalization equations of FIG. 14, FIG. 15, FIG. 16 and FIG. 17.

A fractional position spanning a rotation from A at a local minimum to the next minimum can be determined from the graph of FIG. 6 for a given A, B. A similar statement holds for FIG. 7 given C and D. FIG. 18 which gives the fractional position function, is the mathematical equivalent of this statement. This function repeats N times when traversing the full sensor range with A and B as arguments. The function repeats M times with C, D as the arguments. The equations in FIG. 24 and FIG. 25 are a statement of this property. For real world measurements, these two equations are unlikely to agree exactly due to limited measurement resolution and imperfect linearity. We attribute the discrepancy to error in the lower resolution track as indicated in FIG. 26.

What I claim as my invention is:

1. A contactless absolute rotational position sensor comprised of:
a. A coupling element with a annular track containing 2Mt identical conductive annular segments spaced 360/2Mt degrees apart and an annular track containing 2Nt identical conductive annular segments spaced 360/2Nt degrees apart. Segments in the track containing 2Mt segments which are spaced a multiple of 360/Mt degrees apart are conductively connected. Segments in the track containing 2Nt segments which are spaced a multiple of 360/Nt degrees apart are conductively connected. N, M, t are positive integers with M and N relatively prime.
b. A transceiver element with an annular track containing 4p conductive annular segments. Also, with an annular track containing 4q conductive annular segments. The 4p segments have radial position and size matching the 2Mt segments of the coupling disc. The 4q segments have radial position and size matching the 2Nt segments of the coupling element. The 4p segments consist of 2p pairs of segments with the segments of a pair spaced 180/(Mt) degrees apart. The 4q segments consist of 2q pairs of segments with segments of a pair being spaced 180/(Nt) degrees apart. The 2p pairs are comprised of p pairs spaced (k+0.5)180/(Mt) degrees from the remaining p pairs. The 2q pairs are comprised of q pairs spaced (k+0.5)180/(Nt) degrees from the remaining q pairs. k is any positive integer. Segments in the annular track containing 4p segments which are spaced by a multiple of 360/(Mt) degrees are electrically connected. Segments in the annular track containing 4q segments which are spaced by a multiple of 360/(Nt) degrees are electrically connected. p and q are positive integers.

2. The sensor in 1 where t equals 1.

3. The sensor in 1, where the transceiver element contains 2 annular conductive areas and the coupling element contains two matching annular conductive areas. For the coupling disc, one annular area is electrically connected to every other segment in the track containing 2Mt segments and every other segment in the track containing 2Nt segments. The other annular conductive area is electrically connected to the remaining Mt and Nt annular segments. A potential waveform is applied to the annular conductors of the transceiver element by resistively connecting the positive side of a potential to one annulus while simultaneously resistively connecting the negative side of the potential to the other annulus. After a delay the potential connections are broken. After another delay the connections are made with the opposite potential polarities. After a third delay, these connections are broken. This sequence of making and breaking connections is repeated for as long as position data is desired.

4. The Sensor in 1, where the transceiver element outputs values which vary linearly with respect to the area of overlap of annular segments belonging to a coupling element node and annular segments belonging to a node on the transceiver element. The value may be an analog signal or a digital representation of a numerical value.

5. The Sensor in 1, where the transceiver element outputs a value which varies linearly as the coupling element traverses an angle of 360 divided by t degrees. The value may be an analog signal or a digital representation of a numerical value.

6. The Sensor in 1, where the transceiver element outputs a value which varies linearly as the coupling element traverses an angle of 360 degrees. The value may be an analog signal or a digital representation of a numerical value.
